(19) United States
(12) Patent Application Publication
(10) Pub. No.: US 2024/0222119 A1
(43) Pub. Date: Jul. 4, 2024

(54) PATTERNING BASED ON IN-SITU FORMATION OF BLOCK COPOYLMER THROUGH DEPROTECTION

(71) Applicant: Intel Corporation, Santa Clara, CA (US)

(72) Inventors: Eungnak Han, Portland, OR (US); James Blackwell, Portland, OR (US); Gurpreet Singh, Portland, OR (US); Florian Gstrein, Portland, OR (US)

(73) Assignee: Intel Corporation, Santa Clara, CA (US)

(21) Appl. No.: 18/147,107

(22) Filed: Dec. 28, 2022

(51) Int. Cl. H01L 21/027; H01L 21/02

(52) U.S. Cl. CPC H01L 21/0274; H01L 21/02118; H01L 21/02345; C08F 293/00

(57) ABSTRACT

In-situ formation of a block copolymer through deprotection can provide patterns with flexible pitches. A layer of a protected polymer including a protecting group is formed. One or more portions of the layer may be exposed to light. The exposed portion(s) may be baked after the light exposure. The protecting group is removed after the light exposure or bake so that the protected polymer becomes a deprotected polymer in the exposure portion(s). The deprotected polymer is bonded with the protected polymer in the unexposed portion(s) of the layer but has a different solubility from the protected polymer so that phases of the block copolymer are separated. The phase separation can provide a periodic pattern with various pitches. The solution and roughness of the pattern can be enhanced by using CARs formed with a protected, cross-linked polymer that includes a protective group and a function group with a ratio of 50:50.

### BACKGROUND

Integrated circuit (IC) fabrication usually includes two stages. The first stage is referred to as the front end of line (FEOL). The second stage is referred to as the back end of line (BEOL). In the FEOL, individual components (e.g., transistor, capacitors, resistors, etc.) can be patterned in a wafer. In the BEOL, metal layers, vias, and insulating layers can be formed to get the individual components interconnected. The BEOL usually starts with forming the first metal layer on the wafer. The first metal layer is often called M0. More metal layers can be formed on top of M0, and these metal layers are often called M1, M2, and so on. Patterning of components in the FEOL stage or the BEOL stage can be performed through directed self-assembly (DSA) of block copolymers, which is often facilitated by chemically amplified photoresists (also referred to as “chemically amplified resists (CAR)”).

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an IC device comprising an FEOL section and a BEOL section, according to some embodiments of the disclosure.

FIG. 2 illustrates a multi-pitch layer, according to some embodiments of the disclosure.

FIGS. 3A-3H illustrate formation of a guiding pattern through CAR structures, according to some embodiments of the disclosure.

FIGS. 4A-4F illustrate in-situ formation of a block copolymer through a deprotection reaction, according to some embodiments of the disclosure.

FIG. 5 illustrate deprotection and breakage of cross-links in a polymer after exposure to ultraviolet light, according to some embodiments of the disclosure.

FIGS. 6A-6B are top views of a wafer and dies that may include one or more multi-pitch patterns, according to some embodiments of the disclosure.

FIG. 7 is a side, cross-sectional view of an example IC package that may include one or more IC devices having one or more multi-pitch patterns, according to some embodiments of the disclosure.

FIG. 8 is a cross-sectional side view of an IC device assembly that may include components having one or more IC devices implementing one or more multi-pitch patterns, according to some embodiments of the disclosure.

FIG. 9 is a block diagram of an example computing device that may include one or more components with one or more multi-pitch patterns, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

Patterns of metal lines, insulators, or vias in IC devices are often generated through DSA of block copolymers. Phase separation during the DSA of a block copolymer can produce a DSA pattern that includes lamellar structures of polymers. Taking a block copolymer including polymer A and polymer B for example, the DSA of the block copolymer may form lamellar structures including polymer A and lamellar structures including polymer B. The two types of lamellar structures alternate. The center-to-center distance between two adjacent lamellar structures including the same polymer may define a pitch of the DSA pattern.

However, DSA of a block copolymer is limited to a single pitch pattern. The pitch of the DSA pattern is fixed, e.g., based upon the molecular weight of the block copolymer. Examples of pitches of DSA patterns may include, for example, 33 nanometers (nm), 34 nm, 36 nm, 38 nm, 39 nm, and so on. However, the fabrication of an IC device may require formation of a DSA pattern over an underlayer that has a multi-pitch pattern, meaning the underlayer has at least two different pitches. For instance, the layer may have conductive structures (e.g., contacts, metal lines, etc.) that have different dimensions, such as different lengths. The pitch of DSA pattern cannot match all the pitches of the underlayer. Also, the DSA pattern may have poor resolution or high roughness that can deteriorate the performance of the IC device. For instance, the DSA pattern may have a high line edge roughness, which indicates a deviation of an edges in a pattern structure from the mean straight line. Thus, improved technologies for patterning, such as multi-pitch patterning, are needed.

Embodiments of the present disclosure may improve on at least some of the challenges and issues described above by patterning IC components based on in-situ formation of block copolymers through deprotection reactions. The in-situ formation of block copolymers through deprotection reactions can provide unlimited pitch range and can provide better resolution and lower roughness. The in-situ formation of block copolymers may be guided by using CARs formed with protected, cross-linked polymers, which can further improve the resolution and roughness.

In various embodiments of the present disclosure, phase separation of a block copolymer may be facilitated through a deprotection reaction in a polymer. A layer of the polymer may be formed over an underlayer. The layer may be homogenous. In some embodiments, the polymer has a molecular weight (e.g., an average molecular weight) of at least 10 kilogram per mole (kg/mol). In an embodiment, the molecular weight of the polymer may be in a range from about 10 kg/mol to 100 kg/mol. The polymer includes a protecting group. The protecting group may be a non-polar functional group, such as a hydrophobic functional group. The polymer is also referred to as a protected polymer. The protecting group may be removed (e.g., be converted to a functional group) through a deprotection reaction during or after exposure to light, such as ultraviolet light. The layer may also include a photoacid generator that can generate acid during or after light exposure. The acid can catalyze the deprotection reaction. The deprotection reaction may convert the protecting group to a different functional group, such as a polar functional group. The polar functional group may be a hydrophilic functional group. One or more portions of the layer may be blocked from the light while one or more other portions of the layer may be exposed to the light to form a heterogenous layer. In the exposed portion(s), the protected polymer is converted to a deprotected polymer as the protecting group is removed. In contrast, the unexposed portion(s) of the layer still has the protected polymer. A molecule of the protected polymer may be bonded with a molecule of the deprotected polymer, which forms a molecule of the block copolymer. The deprotected polymer has a different rigidity from the protected polymer, which allows one of the two polymers to be removed by selective etch while the other polymer is not removed. Patterning of IC components (e.g., metal lines, vias, hard masks, etc.) can be performed based on the pattern of the protected polymer and deprotected polymer.

As the phase separation of the block copolymer is caused by the light exposure, the pitch of the block copolymer can be controlled by controlling dimensions of the exposed portion(s) or the unexposed portion(s), e.g., by controlling positions or dimensions of masks that blocks the unexposed portion(s) from the light. Accordingly, the in-situ formation of the block copolymer can provide patterns with flexible pitch ranges or even unlimited pitch ranges. Also, the resolution and roughness of the patterns can be better compared with patterns formed through conventional DSA of block copolymers.

In some embodiments, the resolution and roughness of the patterns can be further improved by using CARs formed with protected, weakly cross-linked polymers. For instance, the underlayer may include a layer of a protected, cross-linked polymer, which may include a main chain onto which a protecting group and a functional group are attached. The molar ratio of the protecting group and the functional group may be 50:50. The functional group can be bonded with the protecting group so that the molecules of the polymer can be cross-linked through the bonding between the functional group and the protecting group. The polymer has a molecular weight (e.g., an average molecular weight) of at least 1 kg/mol. In some embodiments, the molecular weight of the polymer is in a range from about 1 kg/mol to about 10 kg/mol.

CAR structures may be formed by exposing certain portions of the layer to light. Post-exposure bake may also be used. The light exposure (and optional pose-exposure bake) can remove the protecting group. As the protecting group is removed, the cross-links are also broken. The protected, cross-linked polymer is converted to a deprotected, uncross-linked polymer in the exposed portions. The deprotected, uncross-linked polymer can have a significantly higher solubility than the protected, cross-linked polymer and therefore, can be dissolved in a solvent that does not dissolve the protected, cross-linked polymer. Thus, the unexposed portions of the layer may be reserved and form the CAR structures. The difference in the solubilities of the exposed portions and the unexposed portions can be enhanced by the breakage of the cross-links, in addition to the removal of the protecting group. The enhanced contrast can improve resolution and roughness of the CAR structures. The CAR structures can guide the in-situ formation of the block copolymer.

Compared with conventional DSA of block copolymers, the present disclosure provides a patterning method that not only can provide patterns with unlimited pitch range but also can improve resolution and roughness of the patterns. Thus, the present disclosure provides a more advantageous patterning method.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections. A longitudinal axis of a structure refers to a line (e.g., an imaginary line) that runs down the center of the structure in a direction perpendicular to a transverse cross-section of the structure.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−8% of a target value, e.g., within +/−5% of a target value or within +/−2% of a target value, based on the context of a particular value as described herein or as known in the art. Also, the term “or” refers to an inclusive “or” and not to an exclusive “or.”

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

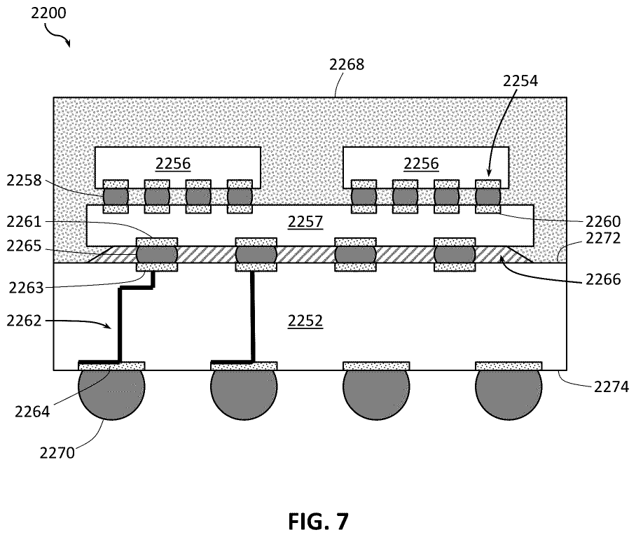

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 7.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of one or more multi-pitch patterns fabricated through one or more cross-linkable copolymers as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various one or more multi-pitch patterns fabricated through one or more cross-linkable copolymers as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

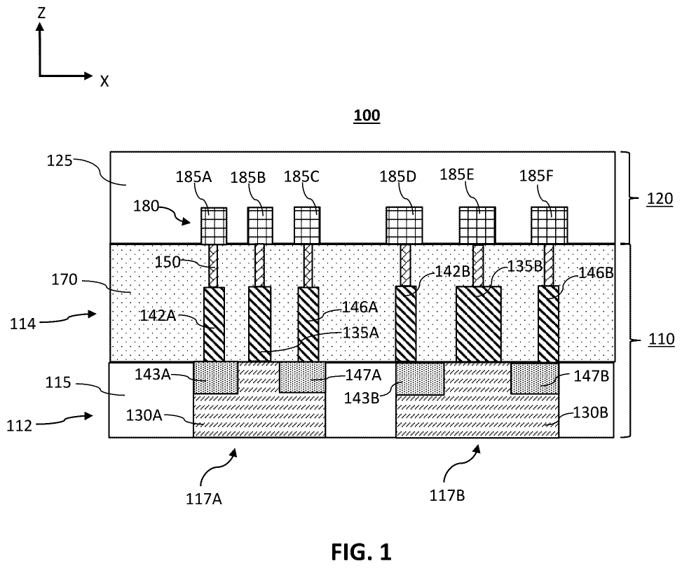

FIG. 1 illustrates an IC device 100 comprising an FEOL section 110 and a BEOL section 120, according to some embodiments of the disclosure. As shown in FIG. 1, the FEOL section 110 includes layers 112 and 114, which include a support structure 115, two transistors 117A and 117B (collectively referred to as “transistors 117” or “transistor 117”), vias 150 (individually referred to as “via 150”), and an electrical insulator 170. The BEOL section 120 includes an electrical insulator 125 and a metal layer 180 that includes metal lines 185A-185F (collectively referred to as “metal lines 185” or “metal line 185”).

In the embodiments of FIG. 1, the metal layer 180 is M0, i.e., the metal layer arranged closest to the FEOL section 110. In other embodiments, the metal layer 180 may be M1, M2, etc. For instance, there may be one or more other metal layers arranged between the metal layer 180 and the FEOL section 110. Also, the IC device 100 may include fewer, more, or different components. For instance, the FEOL section 110 may include more transistors, or other semiconductor devices not shown in FIG. 1. Also, the BEOL section 120 may include one or more other metal layers, which may be coupled to at least one of the metal lines 185. The metal layer 180 may include a different number of metal lines 185, insulative spacing structures, or vias 150.

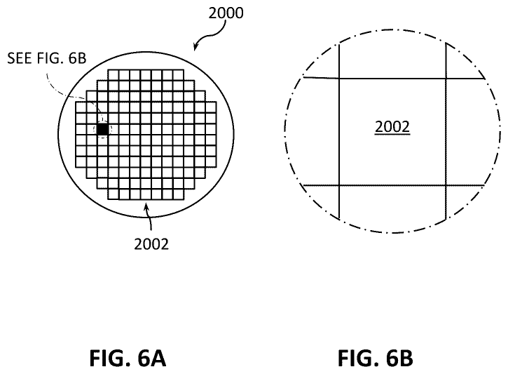

The support structure 115 may be any suitable structure, such as a substrate, a die, a wafer, or a chip, based on which the transistors 117 can be built. The support structure 115 may, e.g., be the wafer 2000 of FIG. 6A, discussed below, and may be, or be included in, a die, e.g., the singulated die 2002 of FIG. 6B, discussed below. In some embodiments, the support structure 115 may be a semiconductor substrate composed of semiconductor material systems including, for example, N-type or P-type materials systems, and, in some embodiments, the channel region 130, described herein, may be a part of the support structure 115. In some embodiments, the semiconductor substrate may be a crystalline substrate formed using a bulk silicon or a silicon-on-insulator substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. In some embodiments, the substrate may be non-crystalline. In some embodiments, the support structure may be a printed circuit board (PCB) substrate. One or more transistors, such as the transistors 117 may be built on the support structure 115.

Although a few examples of materials from which the support structure 115 may be formed are described here, any material that may serve as a foundation upon which an IC may be built falls within the spirit and scope of the present disclosure. In various embodiments, the support structure 115 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 115 may provide material “support” in that, e.g., the IC devices/structures described herein are build based on the semiconductor materials of the support structure 115. However, in some embodiments, the support structure 115 may provide mechanical support.

A transistor 117 may be a field-effect transistor (FET), such as metal-oxide-semiconductor FET (MOSFET), tunnel FET (TFET), fin-based transistor (e.g., FinFET), nanoribbon-based transistor, nanowire-based transistor, gate-all-around (GAA) transistor, other types of FET, or a combination of both. The transistor 117A includes a semiconductor structure that includes a channel region 130A, a source region 143A, and a drain region 147A. The transistor 117A includes a semiconductor structure that includes a channel region 130B, a source region 143B, and a drain region 147B. The channel regions 130A and 130B are collectively referred to as “channel regions 130” or “channel region 130.” The source regions 143A and 143B are collectively referred to as “source regions 143” or “source region 143.” The drain regions 147A and 147B are collectively referred to as “drain regions 147” or “drain region 147.”

The semiconductor structure of each transistor 117 may be at least partially in the support structure 115. The support structure 115 may include a semiconductor material, from which at least a portion of the semiconductor structure is formed. The semiconductor structure of a transistor 117 (or a portion of the semiconductor structure, e.g., the channel region 130) may be a planar structure or a non-planar structure. A non-planar structure is a three-dimensional structure, such as fin, nanowire, or nanoribbon. A non-planar structure may have a longitudinal axis and a transvers cross-section perpendicular to the longitudinal axis. In some embodiments, a dimension of the non-planar structure along the longitudinal axis may be greater than dimensions along other directions, e.g., directions along axes perpendicular to the longitudinal axis.

Each channel region 130 includes a channel material. The channel material may be composed of semiconductor material systems including, for example, n-type or p-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group Ill of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nm and 100 nm, including all values and ranges therein.

For some example n-type transistor embodiments (i.e., for the embodiments where the transistor 117 is an NMOS (N-type metal-oxide-semiconductor) transistor or an n-type TFET), the channel material may advantageously include a III-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InxGa1−xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a III-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material 304 may be relatively low, for example below 1015 dopant atoms per cubic centimeter (cm−3), and advantageously below 10¹³ cm⁻³. These materials may be amorphous or polycrystalline, e.g., having a crystal grain size between 0.5 nanometers and 100 nanometers.

For some example p-type transistor embodiments (i.e., for the embodiments where the transistor 117 is a PMOS (P-type metal-oxide-semiconductor) transistor or a p-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³. These materials may be amorphous or polycrystalline, e.g., having a crystal grain size between 0.5 nanometers and 100 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminum zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

In each transistor 117, the source region 143 and the drain region 147 are connected to the channel region 130. The source region 143 and the drain region 147 each includes a semiconductor material with dopants. In some embodiments, the source region 143 and the drain region 147 have the same semiconductor material, which may be the same as the channel material of the channel region 130. A semiconductor material of the source region 143 or the drain region 147 may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminum (Al), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur (S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region 143 and the drain region 147 are the same type. In other embodiments, the dopants of the source region 143 and the drain region 147 may be different (e.g., opposite) types. In an example, the source region 143 has n-type dopants and the drain region 147 has p-type dopants. In another example, the source region 143 has p-type dopants and the drain region 147 has n-type dopants. Example n-type dopants include Te, S, As, tin (Sn), Si, Ga, Se, S, In, Al, Cd, chlorine (CI), iodine (I), fluorine (F), and so on. Example p-type dopants include beryllium (Be), Zn, magnesium (Mg), Sn, P, Te, lithium (Li), sodium (Na), Ga, Cd, and so on.

In some embodiments, the source region 143 and the drain region 147 may be highly doped, e.g., with dopant concentrations of about 1·10²¹ cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region 143 and the drain region 147 may be the regions having dopant concentration higher than in other regions, e.g., higher than a dopant concentration in the channel region 130, and, therefore, may be referred to as “highly doped” (HD) regions.

The channel region 130 may include one or more semiconductor materials with doping concentrations significantly smaller than those of the source region 143 and the drain region 147. For example, in some embodiments, the channel material of the channel region 130 may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region 143 and the drain region 147, for example below 10¹⁵ cm⁻³ or below 10¹³ cm⁻³. Depending on the context, the term “S/D terminal” may refer to a S/D region or a S/D contact or electrode of a transistor.

The transistor 117A also includes a source contact 142A over the source region 143A and a drain contact 146A over the drain region 147A. The transistor 117B also includes a source contact 142B over the source region 143B and a drain contact 146B over the drain region 147B. The source contacts 142A and 142B are collectively referred to as “source contacts 142” or “source contact 142.” The drain contacts 146A and 146B are collectively referred to as “drain contacts 146” or “drain contact 146.” The source contacts 142 and the drain contacts 146 are electrically conductive and may be coupled to source and drain terminals for receiving electrical signals. A source contact 142 or the drain contact 146 includes one or more electrically conductive materials, such as metals. Examples of metals in the source contacts 142 and the drain contacts 146 may include, but are not limited to, Ruthenium (Ru), copper (Cu), cobalt (Co), palladium (Pd), platinum (Pt), nickel (Ni), and so on.

Each transistor 117 also includes a gate that is over or wraps around at least a portion of the channel region 130. The gate of the transistor 117A includes a gate contact 135A. The gate of the transistor 117B includes a gate contact 135B. The gate contacts 135A and 135B are collectively referred to as “gate contacts 135” or “gate contact 135.” The gate contact 135A has a smaller length along the X axis than the gate contact 135B. In an example, the length of the gate contact 135A may be about half of the length of the gate contact 135B. In some embodiments, the source contacts 142 or drain contacts 146 may have the same or similar length along the X axis as the gate contact 135A. In other embodiments, the source contacts 142 or drain contacts 146 may have the same or similar length along the X axis as the gate contact 135B. In some embodiments, the source contacts 142 may have different lengths from each other. The drain contacts 146 may have different lengths from each other.

In each transistor 117, the gate contact 135 can be coupled to a gate terminal that controls gate voltages applied on the transistor 117. The gate contact 135 may include one or more gate electrode materials, where the choice of the gate electrode materials may depend on whether the transistor 117 is a p-type transistor or an n-type transistor. For a p-type transistor, gate electrode materials that may be used in different portions of the gate electrode may include, but are not limited to, Ru, Pd, Pt, Co, Ni, and conductive metal oxides (e.g., ruthenium oxide). For an n-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate contact 135 may include a stack of a plurality of gate electrode materials, where zero or more materials of the stack are workfunction (WF) materials and at least one material of the stack is a fill metal layer. Further materials/layers may be included next to the gate electrode for other purposes, such as to act as a diffusion barrier layer or/and an adhesion layer.

The gate of a transistor 117 may also include a gate insulator (not show in FIG. 1) that separates at least a portion of the channel region 130 from the gate electrode so that the channel region 130 is insulated from the gate electrode. In some embodiments, the gate insulator may wrap around at least a portion of the channel region 130. The gate insulator may also wrap around at least a portion of the source region 143 or the drain region 147. At least a portion of the gate insulator may be wrapped around by the gate electrode. The gate insulator includes an electrical insulator, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

As shown in FIG. 1, the transistors 117 are coupled to the metal layer 180 through the vias 150. The metal layer 180 may facilitate controlling operation of the transistors 117 by providing electrical signals to the transistors 117, such as the source contacts 142, the drain contacts 146, or the gate contacts 135. For purpose of illustration, the metal lines 185A and 185D are coupled to the source contacts 142, the metal lines 185B and 185E are coupled to the gate contacts 135, and the metal lines 185C and 185F are coupled to the drain contacts 146. Each metal line 185 is an electrically conductive structure. A metal line 185 may also be referred to as electrically conductive interconnects or interconnects. The metal layer 180 may also be referred to as an electrically conductive interconnect set or an interconnect set. In some embodiments, a metal line 185 includes one or more metal, such as tungsten (W), molybdenum (Mo), ruthenium (Ru), copper (Cu), other metals, or some combination thereof. The metal lines 185 are shown as rectangles in FIG. 1 for purpose of illustration. The metal lines 185 may have different shapes in other embodiments. Some or all of the metal lines 185 may be at different electrical potentials during operation of the IC device 100. The metal lines 185 are arranged in parallel in FIG. 1. A metal line 185 may have a longitudinal axis along the Y axis. The metal line 185 may have a transvers cross-section perpendicular to the longitudinal axis. In some embodiments, the metal lines 185 have the same or similar height, i.e., the dimension along the Z axis.

The metal lines 185 are insulated from each other by the electrical insulator 125. The electrical insulator 125 includes one or more electrically insulative materials. An electrically insulative material may be a dielectric material, hysteretic material, and so on. Example dielectric material includes oxide (e.g., Si based oxides, metal oxides, etc.), nitride (e.g., Si based nitride, etc.), low-k dielectric, high-k dielectric, and so on. Example hysteretic material include ferroelectric materials, antiferroelectric materials, and so on. The electrical insulator 125 may be referred to as ILD of the BEOL section 120.

The vias 150 can provide a conductive channel between the transistors 117 and the metal layer 180. Each via 150 has an end that is connected to a gate contact 135, source contact 142, or drain contact 146. The other end of the via 150 is connected to a metal line 185. Each via 150 is electrically conductive. A via 150 may include a metal, such as tungsten (W), molybdenum (Mo), ruthenium (Ru), copper (Cu), or other metals. Different vias 150 may include different materials. The vias 150 that are connected to gate contacts may be referred to as VCGs. The vias 150 that are connected to source contacts and drain contacts may be referred to as VCTs. For purpose of illustration, FIG. 1 shows two vias 150 (i.e., the vias that are connected to the metal lines 185B and 185E) that are VCGs and four vias 150 (i.e., the vias that are connected to the metal lines 185 A, 185C, 185D, and 185F) that are VCTs. In other embodiments, the transistors 117 may be coupled to the metal layer 180 through a different number of vias 150. In other embodiments, the electrical connection between the metal layer 180 and the transistors 117 may be different. Also, the transistors 117 may be coupled to one or more other metal layers. Even though not shown in FIG. 1, the metal layer 180 may be coupled with other devices than the transistor 117, such as diodes, power sources, resistors, capacitors, inductors, sensors, transceivers, receivers, antennas, and so on.

The electrical insulator 170 includes one or more electrically insulative materials. An electrically insulative material may be a dielectric material, hysteretic material, and so on. Example dielectric material includes oxide (e.g., Si based oxides, metal oxides, etc.), nitride (e.g., Si based nitride, etc.), low-k dielectric, high-k dielectric, and so on. Example hysteretic material include ferroelectric materials, antiferroelectric materials, and so on. In some embodiments, a portion of the electrical insulator 170 may include a first electrical insulator and a second electrical insulator with the second electrical insulator at least partially surrounding the first electrical insulator.

The vias 150 or metal lines 185 may be formed through patterning over the layer 114 that includes the gate contacts 135, source contacts 142, and drain contacts 146. The gate contacts 135, source contacts 142, and drain contacts 146 may be formed through patterning over an underlayer, such as the layer 112 that includes the channel regions 130, source regions 143, drain regions 147, and the support structure 115. As shown in FIG. 1, the gate contacts 135 have different lengths along the X axis: the gate contact 135B has a greater length than the gate contact 135A. Thus, the layer 114 has two different pitches. The metal layer 180 also have multiple pitches as there are different center-to-center distances between two adjacent metal lines along the X axis (e.g., the center-to-center distance between the metal line 185A and the metal line 185B is different from the center-to-center distance between the metal line 185D and the metal line 185E) or different metal lines 185 (e.g., the metal lines 184A and 185D) have different lengths along the X axis. Additionally or alternatively, the vias 150 may also have multiple pitches.

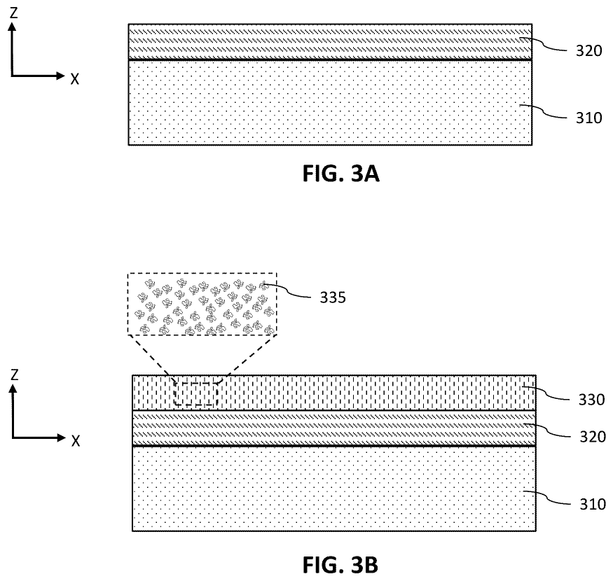

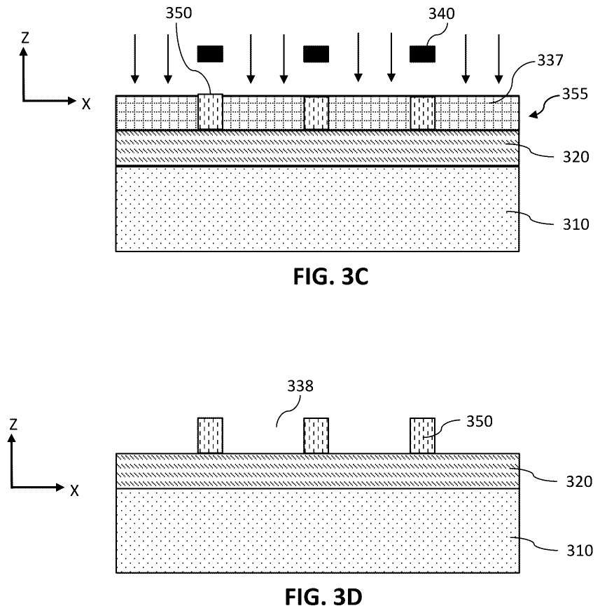

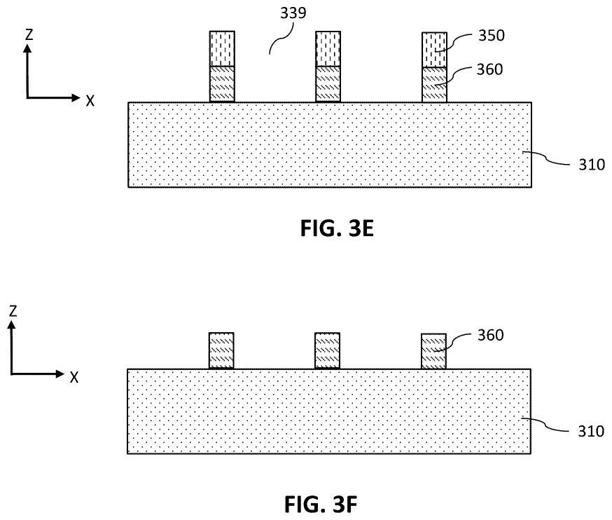

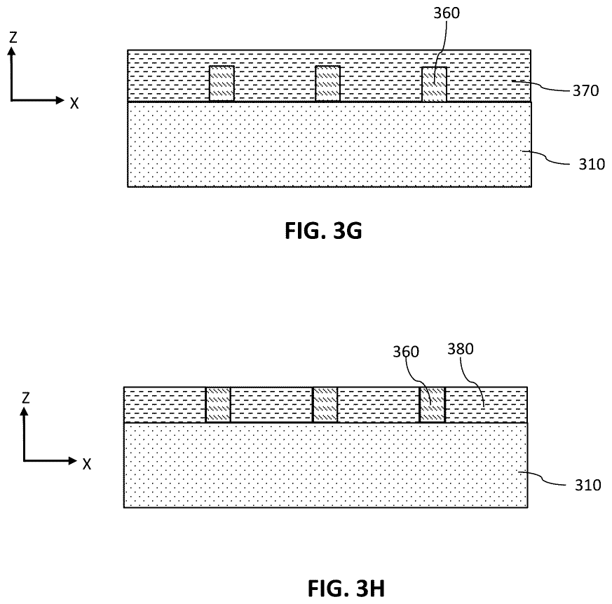

The multi-pitch patterns in the IC device 100 cause challenges to fabricate the components in the IC device 100 based on conventional DSA of block copolymers, as the DSA of a block copolymer typically has one fixed pitch. In some embodiments, the patterning for components in the IC device 100 may be performed by using a block copolymer that is formed in-situ through a deprotection reaction. Using such a block copolymer can also improve the resolution and LER of the patterns. The resolution and LER of the patterns can be further improved by using a chemically amplified resist fabricated with a polymer including a protecting group and a function group with a ratio of 1:1. More details regarding the in-situ formed block copolymer and the chemically amplified resist are provided below in conjunction with FIGS. 3A-3H, 4A-4F, and 5.

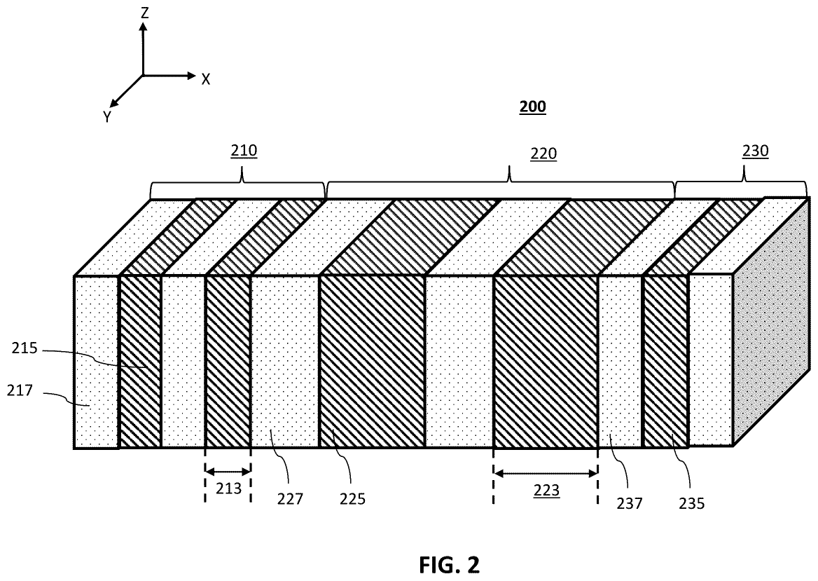

FIG. 2 illustrates a multi-pitch layer 200, according to some embodiments of the disclosure. The multi-pitch layer 200 may be an embodiment of at least part of the layer 114 or the BEOL section 120 in FIG. 1. As shown in FIG. 2, the multi-pitch layer 200 includes a tight pitch region 210, a loose pitch region 220, and another tight pitch region 230. In other embodiments, the multi-pitch layer 200 may include fewer, more or different regions.

The tight pitch region 210 include conductive structures 215 (individually referred to as “conductive structure 215”) and insulative structures 217 (individually referred to as “insulative structure 217”). The conductive structures 215 have longitudinal axes along the Z axis. Two adjacent conductive structures 215 are separated by an insulative structure 217. An example of the conductive structure 215 may be the gate contact 135A in FIG. 1. A pitch 213 of the tight pitch region 210 is a length of a conductive structure 215 along the X axis. In other embodiments, the pitch of the tight pitch region 210 may be a center-to-center distance between two adjacent conductive structures 215, which may be the same or substantially the same as the pitch 213.

The loose pitch region 220 include conductive structures 225 (individually referred to as “conductive structure 225”) and insulative structures 227 (individually referred to as “insulative structure 227”). The conductive structures 225 have longitudinal axes along the Z axis. Two adjacent conductive structures 225 are separated by an insulative structure 227. An example of the conductive structure 225 may be the gate contact 135B or one of the metal lines 185D-185F in FIG. 1. In some embodiments, the loose pitch region 220 has a pitch 223, which is a length of a conductive structure 225 along the X axis. In other embodiments, the pitch of the loose pitch region 220 may be a center-to-center distance between two adjacent conductive structures 225, which may be the same or substantially the same as the pitch 223. The pitch 223 is greater than the pitch 213 of the tight pitch region 210.

The tight pitch region 230 include a conductive structure 235 and insulative structures 237 (individually referred to as “insulative structure 237”). The conductive structure 235 has a longitudinal axis along the Z axis. The conductive structure 235 is separated by a conductive structure 225 in the loose pitch region 220 by an insulative structure 227. For purpose of illustration, FIG. 2 shows one conductive structure 235 in the tight pitch region 230. In other embodiments, the tight pitch region 230 may include more conductive structures 235. A pitch of the conductive structure 235 in the tight pitch region 230 may be the same or similar as the pitch 213 of the tight pitch region 210. An example of the conductive structure 235 may be the gate contact 135A or one of the metal lines 185A-185C in FIG. 1.

An insulative structure 217, 227, or 237 may include a first insulative structure and a second insulative structure. The first insulative structure may be a layer of an electrical insulator that at least partially surrounds the second insulative structure. In some embodiments, the first insulative structure and the second insulative structure may include different insulators. In an example, the first insulative structure may include a nitride, such as silicon nitride, and the second insulative structure may include an oxide, such as silicon oxide.

Due to the differences in the pitches 213 and 223, the multi-pitch layer 200 has a multi-pitch pitch pattern, which causes challenges to pattern over the multi-pitch layer 200 through DSA of block copolymers, as DSA of block copolymer is usually limited to single pitch pattern. The single pitch pattern may be defined by an average molecular weight of the block copolymer. In an example, the average molecular weight block copolymer may be compatible with the pitch pattern of the tight pitch region 210 or 230 so that the conductive structure-insulative structure alternating pattern in the tight pitch region 210 or 230 may function as a guiding pattern for the DSA of the block copolymer. Lamellar structures formed through the self-assembly of the block copolymer can align with the conductive structure and insulative structures in the tight pitch regions 210 and 230.

However, given that the loose pitch region 220 has a different pitch pattern, the average molecular weight block copolymer is incompatible with the pitch pattern of the loose pitch region 220. Lamellar structures would fail to align with the conductive structure 225 or insulative structures 227 in the loose pitch region 220. This can result in undesired DSA single pitch, random fingerprint pattern, horizontal morphology, or some combination thereof over the loose pitch region 220. These undesired patterns formed over the loose pitch region 220 need to be removed, e.g., through cut mask.

FIGS. 3A-3H illustrate formation of a guiding pattern through CAR structures 350, according to some embodiments of the disclosure. FIG. 3A shows a layer 320 formed over an underlayer 310 in a direction along the Z axis. The underlayer 310 may include one or more electrical conductors (e.g., metal lines, gate contact, source or drain contact, vias, etc.) or one or more electrical insulators (e.g., polymer, dielectric materials, etc.). Examples of the underlayer 310 may include the layer 112 in FIG. 1, the layer 114 in FIG. 1, the BEOL section 120 in FIG. 1, or the multi-pitch layer 200 in FIG. 2.

The layer 320 may be formed over the underlayer 310 by depositing one or more polymers onto the top surface of the underlayer 310. The one or more polymers may include a polymer in a block copolymer that is to be formed based on the CAR. Examples of the polymer include polyethylene, polystyrene, poly(methyl methacrylate), polyvinylchloride, polytetrafluorethylene, polydimethylsiloxane, some polyesters, some polyurethanes, acrylics, epoxies, P(t-Buytl Acrylate), polyacrylic acid, polyacrylamide, maleic anhydride polymers, polyethylene, polypropylene, polyacrylonitrile, polybutadiene, polyvinyl acetate, polyacetic acid, polybutyl acrylate, polylactic acid, polycaprolactone, poly(ethylene glycol), polyisoprene, and so on. The polymer may be deposited through chemical vapor deposition (CVD, such as plasma enhanced CVD), atomic layer deposition (ALD), physical vapor deposition (PVD), other types of deposition techniques, or some combination thereof.

In FIG. 3B, another layer 330 is formed over the layer 320. The layer 320 is between the layer 310 and the layer 330 along the Z axis. The layer 330 includes a polymer 335 that is homogenous. FIG. 3 shows a plurality of molecules of the polymer 335. In some embodiments, a molecular weight (e.g., an average molecular weight) of the homogenous polymer is no greater than 10 kg/mol. Examples of the homogenous polymer include polymers made from polymerization of norbornene or other monomers susceptible to ring-opening metathesis polymerization (ROMP). These lead to homopolymer with fixed ratio of functional groups based on structure of monomer. The homogenous polymer may be deposited onto the top surface of the layer 320 to form the layer 330, e.g., through spin coating.

The layer 330 may be a photoresist film. The polymer 335 may have one or more photoresist properties. The polymer 335 may include a protecting group, such as acid-labile protecting groups, that are attached to the main chain of the polymer 335. The protecting group may be a hydrophobic (non-polar) functional group. Examples of the protecting group include ester (e.g., tertiary or other esters), anhydride, organic carbonate, other hydrophobic (non-polar) functional groups that can be converted to hydrophilic (polar) functions groups (e.g., carboxylic acids, phenols, etc.), and so on. In some embodiments, the layer may also include a photoacid generator. The photoacid generator may be a compound that, upon exposure to light, generates one or more photoacids (also referred to as “acids”). Examples of the photoacid generator include triarylsulfonium or diaryliodonium perfluoroarylsulfonates that include perfluoroaryl groups, such as pentafluorophenyl(C₆F₅—), nonafluorobiphenyl (C₁₂F₄—), heptafluoronaphthyl (C₁₀F₇—), or other variants.

In FIG. 3C, various portions of the layer 330 is exposed to light, which is illustrated by the arrows in FIG. 3. The light may be ultraviolet light. In some embodiments, the light is extreme ultraviolet radiation. A wavelength of the light may be in a range from 10 nm to 124 nm. The other portions of the layer 330 are blocked from the light by the masks 340 (individually referred to as “mask 340”). In some embodiments, a mask 340 is placed over the corresponding portion of the layer 330. The mask 340 may be in contact with the portion of the layer 330, e.g., the mask 340 may be placed on the top surface of the portion of the layer 330. In other embodiments, the mask 340 may be applied on a light source emitting the light.

The polymer 335 in the unexposed portions of the layer 330 still has the protecting group. The protecting group may function as a dissolution inhibitor that makes the polymer 335 have a low solubility, e.g., in inorganic solvents (such as aqueous based solvents). For instance, a dissolution rate of the polymer 335 in the unexposed portions of the layer 330 may be no greater than 10 nanometer/minute (nm/min). The polymer 335 with the protecting group may be soluble in organic solvents.

In the exposed portions of the layer 330, the protecting group in the polymer 335 is removed through a deprotection reaction. For instance, the protecting group may be converted to a functional group that does not inhibit dissolution of the photoresist polymer. The removal of the protecting group may be facilitated by the photoacid generator in the layer 330. In an example, after exposure to ultraviolet light, the photoacid generator in the layer 330 may decompose, which may generate one or more acids within the exposed portions of the layer 330. The one or more acids can attack the protecting group in the polymer 335, causing an acid-catalyzed deprotection reaction. In some embodiments, the deprotection reaction may occur during a post-exposure bake. For instance, the layer 330 (or exposed portions of the layer 330) may be heated after the exposure to the light. The one or more acids may act as a catalyzer of the deprotection reaction and are not consumed during the deprotection reaction. In some embodiments, a molecule of the photoacid generator may trigger many (e.g., hundreds, thousands, etc.) deprotection reactions, which can therefore, amplify the efficiency of the light radiation. In order to control acid diffusion and thus the extent of deprotection reaction, quencher molecules may also be included in the polymer 335. The quencher molecules may include bases, such as trialkylamines or photoactive species based on triarylsulfonium salts containing carboxylate (e.g., PhCO2-), hydroxide, or other anions as active bases. The bases may react with the acid (e.g., strong acid) created from the photoacid generator.

As a result of the deprotection reaction in the exposed portions of the layer 330, the layer 330 is converted to a new layer 355. The layer 355 includes structures 337 (individually referred to as “structure 337”) and CAR structures 350 (individually referred to as “CAR structure 350”), where the structures 337 alternative with the CAR structures 350, constituting a periodic pattern. The structures 337 are the unexposed portions of the layer 330 and include the polymer 335 with the protecting group. The CAR structures 350 are generated from the deprotection reaction and include a different polymer with the functional group converted from the protecting group through the deprotection reaction (e.g., ester to carboxylic acid).

In FIG. 3D, the structures 337 are removed, e.g., by dissolving the structures 337 in a solvent, such as an organic solvent. The organic solvent may be 2-heptanone, n-butyl acetate, cyclohexanone, or other types of organic solvent. The removal of the structures 337 is based on the differentiated solubilities of the structures 337 and the CAR structures 350. The CAR structures 350 are not dissolvable or have a significantly lower dissolution rate than the structures 337 in the solvent due to the presence of the protecting group. Thus, the CAR structures 350 are not removed. The removal of the structures 337 forms openings 338 (individually referred to as “opening 338”).

In the embodiments of FIGS. 3A-3H, the CAR structures 350 are formed through a negative tone development process, in which the structures 337 (i.e., the exposed portions of the layer 330) are removed. The CAR structures 350 may be referred to as positive resist structures. In other embodiments, CAR structures may be formed through a positive tone development process, in which the unexposed portions can have a higher solubility than the exposed portions so that the unexposed portions are removed, e.g., by using a solvent. Examples of the solvent for the positive tone development include aqueous tetramethylammonium hydroxide, other tetraalkylammonium hydroxides, alcohols, water, and so on.

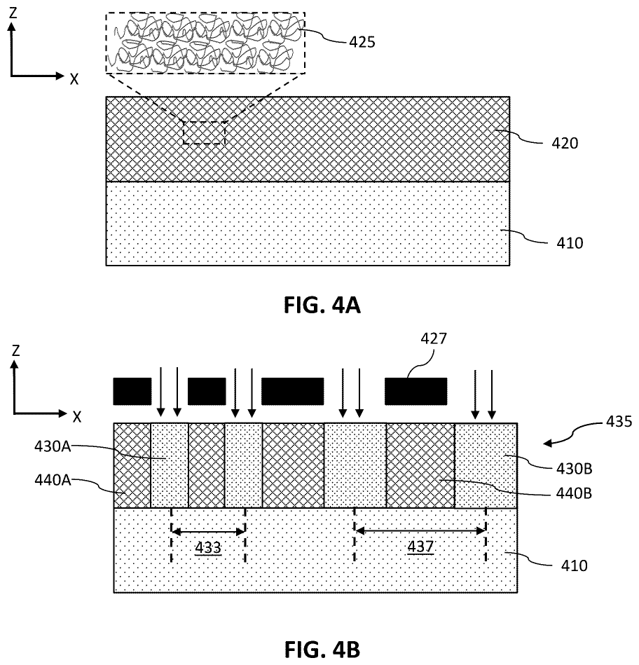

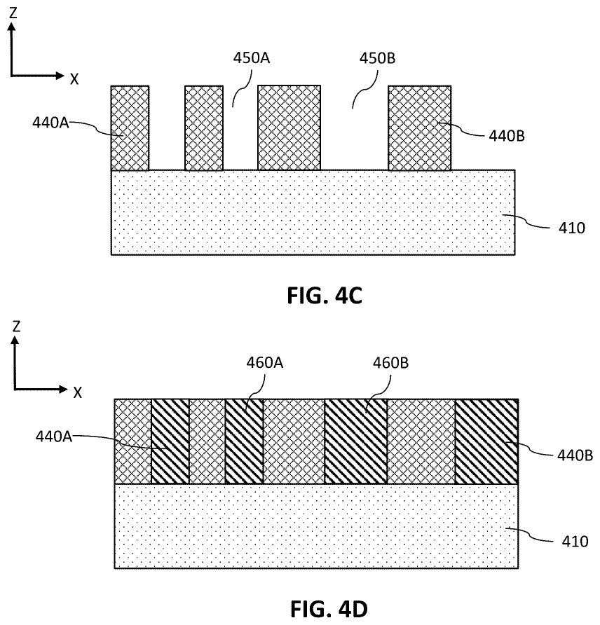

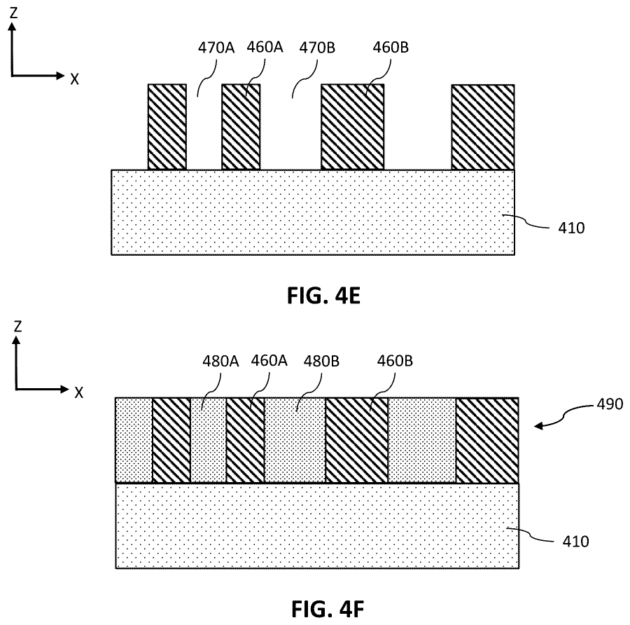

In some embodiments, the pattern of the CAR structures 350 are used as a guiding pattern for forming a block copolymer, e.g., a block copolymer formed through the process illustrated in FIGS. 4A-4F. In other embodiments, further steps may be performed (e.g., the steps in FIGS. 3E-3H) to form the guiding pattern.

The resolution and roughness (e.g., LER) of the edges of the CAR structures 350 can influence the efficiency of the guiding pattern. Higher resolution and lower roughness can make the guiding pattern more effective in patterning components of IC devices. In some embodiments, the resolution and roughness of the CAR structures 350 may be improved by using a polymer with enhanced dissolution inhibitor. The polymer, for example, includes a protecting group and a functional group with a ratio of 50:50. The polymer can be used as the polymer 335 to form the layer 330. The protecting group may function as a dissolution inhibitor as described above. The functional group may function as a photosensitizer, photoacid generator, and so on. Without or before light exposure, the functional group in a molecule of the polymer may cross-link with the protecting group in another molecule of the polymer. The cross-linking between the functional group and the protecting group can function as an additional dissolution inhibitor in addition to the protecting group so that the dissolution of the polymer can be further inhibited.

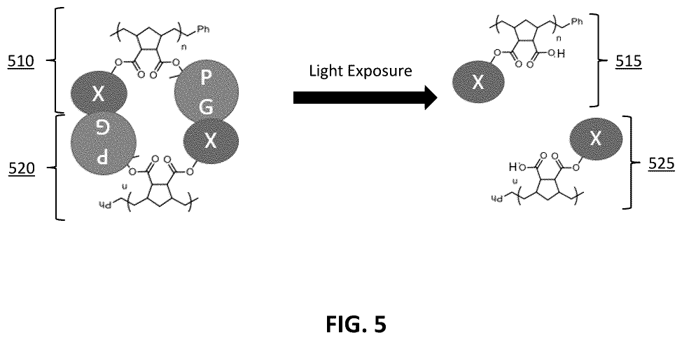

After light exposure or post-exposure bake, the protecting group may be removed. The cross-link between the protecting group and the function group is also removed. The removal of both the protecting group and the cross-link, compared with the removal of the merely protecting group, can enhance the contrast in the solubilities of the structures 337 and the CAR structures 350. The enhanced contrast can maximize the dissolution of the structures 337 in the solvent but minimize the dissolution of the CAR structures 350 in the solvent and therefore, provide a greater resolution and lower roughness. More details regarding the polymer with enhanced dissolution inhibitor are described below in conjunction with FIG. 5.

In FIG. 3E, portions of the layer 320 that are under the openings 338 are removed, e.g., through polish or etch, forming new openings 339. The remaining portions of the layer 320 constitute structures 360 (individually referred to as “structure 360”). Each structure 360 is under a CAR structure 350. In some embodiments, a length of the structure 360 is the same or substantially the same as the CAR structure 350. One or more edges of the structure 360 (e.g., the side edges perpendicular to the X axis) are aligned with corresponding edges of the CAR structure 350. In FIG. 3F, the CAR structures 350 are removed, e.g., through polish or etch.

In FIG. 3G, a polymer 370 is provided, e.g., deposited onto the underlayer 310 and the structures 360. The polymer 370 may be different from the polymer in the structures 360. In some embodiments, the polymer 370 may be a polymer in a block copolymer to be formed. Examples of the polymer include polyethylene, polystyrene, poly(methyl methacrylate), polyvinylchloride, polytetrafluorethylene, polydimethylsiloxane, some polyesters, some polyurethanes, acrylics, epoxies, P(t-Buytl Acrylate), polyacrylic acid, polyacrylamide, maleic anhydride polymers, polyethylene, polypropylene, polyacrylonitrile, polybutadiene, polyvinyl acetate, polyacetic acid, polybutyl acrylate, polylactic acid, polycaprolactone, poly(ethylene glycol), polyisoprene, and so on.

In FIG. 3H, a part of the polymer 370 is removed to form structures 380, e.g., through polish or planarization. The structures 380 may have the same height as the structures 360 along the Z axis. The structures 360 and 380 form a periodic pattern in which the structurers 360 alternative with the structures 380. The periodic pattern of the structures 360 and 380 may be the same or substantially the same as the periodic pattern of the structures 337 and the CAR structures 350. The periodic pattern may be used as a guiding pattern for forming a block copolymer, e.g., the block copolymer in FIGS. 4A-4F.

FIGS. 4A-4F illustrate in-situ formation of block copolymer through a deprotection reaction, according to some embodiments of the disclosure. In FIG. 4A, a layer 420 is formed over a layer 410. The layer 410 may include one or more electrical conductors (e.g., metal lines, gate contact, source or drain contact, vias, etc.) or one or more electrical insulators (e.g., polymer, dielectric materials, etc.). The layer 410 may include the layer 112 in FIG. 1, the layer 114 in FIG. 1, the BEOL section 120 in FIG. 1, or the multi-pitch layer 200 in FIG. 2. Additionally or alternatively, the layer 410 may include a guiding pattern, such as one of the guiding patterns described above in conjunction with FIGS. 3A-3H.

The layer 420 may be formed with a polymer 425. The polymer 425 may be a homogenous polymer. In some embodiments, the polymer 425 may be a surface stabilized polymer, such as a lightly cross-linked polymer, surface grafted polymer, high MW polymer, bottle brush type polymer, and so on. Examples of the homogenous polymer include poly(t-butyl acrylate), polystyrene, or poly(methyl methacrylate) derivative polymer with pendent group that can change hydrophobicity through acid catalyzed deprotection, such as tert-butyl ester, tert-butoxycarbonyloxyalcohol (TBOC), tert-butyloxy carbamate (BOC), and so on. The homogenous polymer may be deposited onto the top surface of the layer 410 to form the layer 420, e.g., through CVD, ALD, PVD, and so on.

In some embodiments, the polymer 425 has a molecular weight (e.g., an average molecular weight) that is in a range from about 10 kg/mol to about 100 kg/mol. The molecular weight of the polymer 425 may be greater than the molecular weight of the polymer 335 in FIGS. 3A-3H. In an embodiment, the molecular weight of the polymer 425 is about 10 times greater than the molecular weight of the polymer 335 in FIGS. 3A-3H. The polymer 425 may include one or more protecting groups, such as acid-labile protecting groups, that are attached to the main chain of the polymer 425. Examples of the protecting groups include ester (e.g., tertiary or other esters), anhydride, organic carbonate, other hydrophobic (non-polar) functional groups that can be converted to hydrophilic (polar) functions groups (e.g., carboxylic acids, phenols, etc.), and so on. In some embodiments, the layer 420 may also include a photoacid generator. The photoacid generator may be a compound that, upon exposure to light, generates one or more photoacids (also referred to as “acids”). Examples of the photoacid generator include triarylsulfonium or diaryliodonium perfluoroarylsulfonates that include perfluoroaryl groups, such as pentafluorophenyl(C₆F₅—), nonafluorobiphenyl (C₁₂F₄—), heptafluoronaphthyl (C₁₀F₇—), or other variants.

In FIG. 4B, various portions of the layer 420 is exposed to light, which is illustrated by the arrows in FIG. 4, to form structures 430A (individually referred to as “structure 430A”) and structures 430B (individually referred to as “structure 430B”). The light may be ultraviolet light. In some embodiments, the light is extreme ultraviolet radiation. A wavelength of the light may be in a range from 10 nm to 124 nm. The other portions of the layer 420 are blocked from the light by masks 427 (individually referred to as “mask 427”). In some embodiments, a mask 427 is placed over the corresponding portion of the layer 420. The mask 427 may be in contact with the portion of the layer 420, e.g., the mask 427 may be placed on the top surface of the portion of the layer 420. In other embodiments, the mask 427 may be applied on a light source emitting the light.

The polymer 425 in the unexposed portions of the layer 420 still has the protecting group. In the exposed portions of the layer 420, the protecting group in the polymer 425 is removed through a deprotection reaction. For instance, the protecting group, which may be a hydrophobic (non-polar) functional group, may be converted to a hydrophilic (polar) functional group. The removal of the protecting group may be facilitated by the photoacid generator in the layer 420. In an example, after exposure to ultraviolet light, the photoacid generator in the layer 420 may decompose, which may generate one or more acids within the exposed portions of the layer 420. The one or more acids can attack the protecting group in the polymer 425, causing an acid-catalyzed deprotection reaction. In some embodiments, the deprotection reaction may occur during a post-exposure bake. For instance, the layer 420 (or exposed portions of the layer 420) may be heated after the exposure to the light. The one or more acids may act as a catalyzer of the deprotection reaction and are not consumed during the deprotection reaction. In some embodiments, a molecule of the photoacid generator may trigger many (e.g., hundreds, thousands, etc.) deprotection reactions, which can therefore, amplify the efficiency of the light radiation.

As a result of the deprotection reaction in the exposed portions of the layer 420, the layer 420 is converted to a new layer 435, which includes structures 430A, 430B, 440A, and 440B. The structures 430A or 430B are individually referred to as structure 430A or 430B. The structures 430A and 430B are collectively referred to as referred to as structures 430 or structure 430. The structures 440A or 440B are individually referred to as structure 440A or 440B. The structures 440A and 440B are collectively referred to as referred to as structures 440 or structure 440.

The structures 430 are the unexposed portions of the layer 420 and include the polymer 425 with the protecting group, i.e., the protected polymer. The structures 440 are generated from the deprotection reaction and include a new polymer with the functional group converted from the protecting group through the deprotection reaction, i.e., a deprotected polymer. The light exposure (and optionally, post-exposure bake) forms a block copolymer through the in-situ deprotection. A molecule of the protected polymer and a molecule of the deprotected polymer may constitute a molecule of the block copolymer. The molecule of the protected polymer and the molecule of the deprotected polymer may be connected through one or more chemical bonds. For instance, the main chains of the two polymers are connected through one or more chemical bonds. The block copolymer has a binary nature: i.e., protected vs. deprotected, versus the polymer 425 in FIG. 4A is homogenous. The different phases of the block copolymer have different properties, such as different mechanical properties (e.g., different rigidity), or other different physical or chemical properties. The in-situ deprotection results in the phase separation of the block copolymer.

The in-situ formation of the block copolymer through deprotection can be more advantageous than DSA of block copolymers, as the in-situ formation of the block copolymer is not limited to a single pitch. As shown in FIG. 4B, the layer 435 has two pitches 433 and 437, which are different. The pitch 437 is larger than the pitch 433. For purpose of illustration, the pitch 433 is a center-to-center distance along the X axis between the two structures 430A, and the pitch 433 is a center-to-center distance along the X axis between the two structures 430B. In other embodiments, a pitch of the layer 435 may be a center-to-center distance along the X axis between the two structures 440A, a center-to-center distance along the X axis between the two structures 440B, or a length of a structure 430A or 430B along the X axis, or a length of a structure 440A or 440B along the X axis. Also, the layer 435 may include a different number of pitches, such as one pitch, three pitches, etc.

The pitches 433 and 437 of the layer 435 may be controlled by controlling the positions or lengths of the masks 427. Thus, the in-situ formation of the block copolymer can be used for multi-pitch patterning. The in-situ formation of the block copolymer can even provide unlimited pitch range. In contrast, conventional DSA of block copolymers produces a single pitch and many further processing steps are needed to produce a different pitch. Thus, the in-situ formation of the block copolymer provides a more efficient method for multi-pitch patterning.

In some embodiments, a subsequent thermal or solvent annealing step can be applied to take advantage of the phase separation of these heterogenous polymers (i.e., the protected polymer and the deprotected polymer) to improve roughness or remove potential defect structures, such as line bridge. Additionally or alternatively, a guiding pattern may exist in the layer 410 to improve resolution or roughness. For instance, one or more edges of a structure 430A or 430B (e.g., edges perpendicular to the X axis) may be aligned with corresponding edges of a guiding structure in the layer 410. Examples of the guiding structure may include CAR structures 350, structures 337, structures 360, or structures 380 in FIGS. 3A-3H. The periodic pattern of the structures 430A and 430B can be used to fabricate components in IC devices, such as conductive structures (e.g., the gate contacts 135, the source contacts 142, the drain contacts 146, the vias 150, the metal lines 185, etc.), insulative structures (e.g., ILDs, hard masks, etc.), and so on.

In FIG. 4C, the structures 430 are removed. In some embodiments, the structures 430 may be removed through etch, such as wet etch, dry etch, infiltration, and so on. Due to the different properties of the structures 430 and 440, the etch can be selective etch. For instance, the rate of etching the structures 430 can be significantly higher than the rate of etching the structures 440. The structures 440 are barely removed or not removed at all. Openings 450A and 450B are formed. An opening 450A is formed by removing a structure 430A, and an opening 450B is formed by removing a structure 430B.

In FIG. 4D, the openings 450A and 450B are filled with one or more electrically conductive materials (e.g., metals) to form conductive structures 460A and 460B. The conductive structures 460A and 460B may have the same or similar lengths along the X axis as the structures 430A and 430B, respectively. Thus, the conductive structures 460A and 460B have two different pitches.

In FIG. 4E, the structures 440 are removed, e.g., through etching. The structures 440 may have a high etching rate than the conductive structures 460A and 460B. The conductive structures 460A and 460B may be barely removed or not removed at all by the etching. Openings 470A and 470B are formed. An opening 470A is formed by removing a structure 440A, and an opening 470B is formed by removing a structure 440B.

In FIG. 4F, insulative structures 480A and 480B are formed in the openings 470A and 470B, respectively. The conductive structures 460A and 460B and the insulative structures 480A and 480B constitute a layer 490 over the layer 410. The pattern in the layer 490 may match (e.g., the same or substantially the same as) the pattern of the layer 435 in FIG. 4B. For instances, the layer 490 may have the same or substantially the same pitches as the layer 435.

Even though the conductive structures 460A and 460B and the insulative structures 480A and 480B are patterned based on the in-situ formation of block copolymer in the embodiments of FIGS. 4A-4F, other types of structures can also be patterned based on the in-situ formation of block copolymer in the embodiments of FIGS. 4A-4F. Also, fabrication steps not shown in FIGS. 4A-4F can be further performed. For instance, other IC components may be patterned over the layer 490 based on the in-situ formation of block copolymer or another block copolymer.

FIG. 5 illustrate deprotection and breakage of cross-links in a polymer after exposure to ultraviolet light, according to some embodiments of the disclosure. The polymer may be a homogeneous polynorbornene class of polymer. The polymer may be an embodiment of the polymer 335 in FIG. 3B. For purpose of simplicity and illustration, FIG. 5 shows two molecules 510 and 520 of the polymer. Each of the molecules 510 and 520 includes a functional group (X) and a protecting group (PG) that are attached to the main chain of the polymer. Examples of the functional group (X) include phenols, carboxylic acids, amides, pyrroles, ureas, or other weakly acidic groups that can form a hydrogen bond with ester in the protecting group (PG). Alternatively, X can be one or more perfluoroaryl groups (such as —C₆F₅, —C₁₀F₇, —C₁₂F₉, etc.) that can interact with certain embodiments of the protecting group (PG), such as embodiments where the protecting group (PG) is —CMe₂Ph or —CMe₂Ar. Examples of the protecting group (PG) include tertiary esters, —CO₂R (R may be tBu, i.e., tert-butylphenol), methyladamantyl, —CMe₂Ph (Me stands for methyl group, and Ph stands for phenyl group), —CMe₂Ar ((Me stands for methyl group, and Ar stands for aryl group)), and so on. In some embodiments, the molar ratio of the functional group (X) to the protecting group (PG), which is the number of moles of the functional group (X) to the number of moles of the protecting group (PG), in the polymer is 50:50. The molar ratio may be defined in the monomer used to form the polymer through polymerization, and the functional group (X) and the protecting group (PG) may be present in the monomer with a 1:1 molar ratio. Molar ratio may also be referred to as mole ratio.

As shown in FIG. 5, the functional group (X) in the molecule 510 is cross-linked with the protecting group (PG) in the molecule 520. Also, the protecting group (PG) in the molecule 510 is cross-linked with the functional group (X) in the molecule 520. There may be one or more chemical bonds between each functional group (X) and the corresponding protecting group (PG). Thus, the polymer is protected and cross-linked.

The polymer is exposed to light, as shown in FIG. 5. In some embodiments, a post-exposure bake may be performed. The light exposure (and optional post-exposure bake) breaks the cross-links between the functional groups (X) and the protecting groups (PG) and removes the protecting groups (PG). The protecting groups (PG) may be converted to a functional group, which may be different from the functional groups (X). In some embodiments, a photoacid generator is used to generate acid during or after the light exposure, and the acid can catalyze the deprotection reaction that removes the protecting groups (PG). The photoacid generator may be PFAS (polyfluoroalkyl substance) free, i.e., the photoacid generator includes no PFAS. In some embodiments, the photoacid generator may include perfluorarylsulfonate anions, such as C₆F₅SO₃⁻, C₁₂F₉SO₃⁻, C₁₀F₇SO₃⁻, and so on.

The molecule 510 is converted to a new molecule 515, which does not have the protecting group (PG) but still has the main chain and the functional group (X). Similarly, the molecule 520 is converted to a new molecule 525, which does not have the protecting group (PG) but still has the main chain and the functional group (X). Accordingly, the protected, cross-linked polymer is converted to a deprotected, uncross-linked polymer. The deprotected, uncross-linked polymer may have a higher solubility in inorganic solvents.

FIGS. 6A-6B are top views of a wafer 2000 and dies 2002 that may include one or more multi-pitch patterns, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 7. The wafer 2000 may be composed of semiconductor material and may include one or more dies 2002 having IC devices formed on a surface of the wafer 2000. Each of the dies 2002 may be a repeating unit of a semiconductor product that includes any suitable IC (e.g., ICs including one or more multi-pitch patterns as described herein). After the fabrication of the semiconductor product is complete (e.g., after manufacture of metal lines as described herein), the wafer 2000 may undergo a singulation process in which each of the dies 2002 is separated from one another to provide discrete “chips” of the semiconductor product. In particular, devices that include one or more multi-pitch patterns as disclosed herein may take the form of the wafer 2000 (e.g., not singulated) or the form of the die 2002 (e.g., singulated). The die 2002 may include one or more diodes, one or more transistors (e.g., one or more III-N transistors as described herein) as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a SRAM (static random-access memory) device), a logic device (e.g., an AND, OR, NAND, or NOR gate), or any other suitable circuit element. Multiple ones of these devices may be combined on a single die 2002.

FIG. 7 is a side, cross-sectional view of an example IC package 2200 that may include one or more IC devices having one or more multi-pitch patterns, according to some embodiments of the disclosure. In some embodiments, the IC package 2200 may be a system-in-package (SiP).

As shown in FIG. 7, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 7 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 7 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

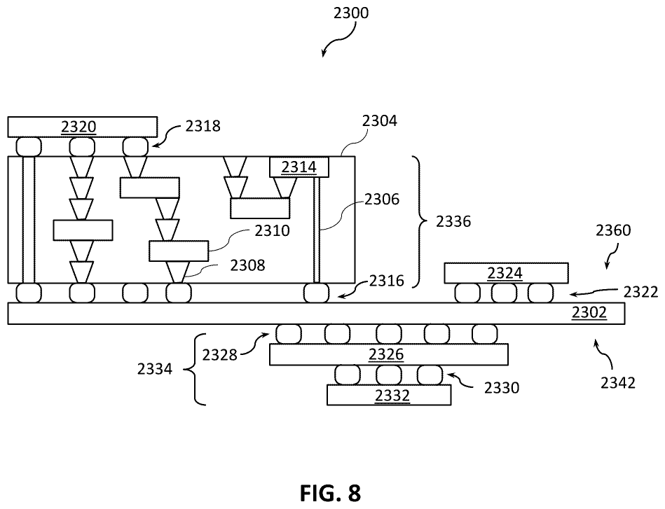

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 7 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 8.

The dies 2256 may take the form of any of the embodiments of the die 2002 discussed herein and may include any of the embodiments of an IC device having one or more multi-pitch patterns. In embodiments in which the IC package 2200 includes multiple dies 2256, the IC package 2200 may be referred to as a multi-chip package. Importantly, even in such embodiments of an MCP implementation of the IC package 2200, one or more multi-pitch patterns may be provided in a single chip, in accordance with any of the embodiments described herein. The dies 2256 may include circuitry to perform any desired functionality. For example, one or more of the dies 2256 may be ESD protection dies, including one or more multi-pitch patterns as described herein, one or more of the dies 2256 may be logic dies (e.g., silicon-based dies), one or more of the dies 2256 may be memory dies (e.g., high bandwidth memory), etc. In some embodiments, any of the dies 2256 may include one or more multi-pitch patterns, e.g., metal lines as discussed above; in some embodiments, at least some of the dies 2256 may not include any III-N diodes with n-doped wells and capping layers.

The IC package 2200 illustrated in FIG. 7 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 7, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 8 is a cross-sectional side view of an IC device assembly 2300 that may include components having one or more IC devices implementing one or more multi-pitch patterns, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices implementing one or more multi-pitch patterns in accordance with any of the embodiments disclosed herein; e.g., any of the IC packages discussed below with reference to the IC device assembly 2300 may take the form of any of the embodiments of the IC package 2200 discussed above with reference to FIG. 7 (e.g., may include one or more multi-pitch patterns in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 8 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 7), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 6B), an IC device (e.g., the IC device of FIG. 1), or any other suitable component. In particular, the IC package 2320 may include one or more multi-pitch patterns as described herein. Although a single IC package 2320 is shown in FIG. 8, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a loose pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 8, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF devices, power amplifiers, power management devices, antennas, arrays, sensors, and microelectromechanical systems (MEMS) devices may also be formed on the interposer 2304. In some embodiments, the IC devices implementing one or more multi-pitch patterns as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 8 includes a package-on-package structure 2334 coupled to the second face 2342 of the circuit board 2302 by coupling components 2328. The package-on-package structure 2334 may include an IC package 2326 and an IC package 2332 coupled together by coupling components 2

such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

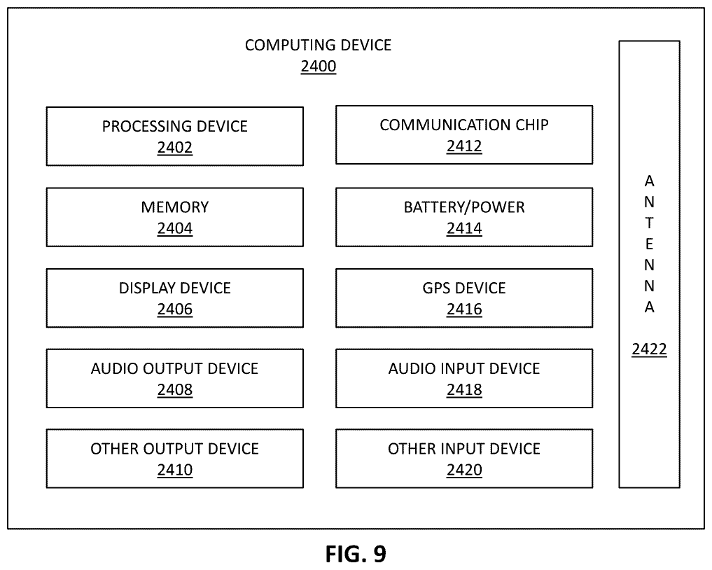

FIG. 9 is a block diagram of an example computing device 2400 that may include one or more components with one or more IC devices having one or more multi-pitch patterns, according to some embodiments of the disclosure. For example, any suitable ones of the components of the computing device 2400 may include a die (e.g., the die 2002 of FIG. 6B) including one or more multi-pitch patterns, according to some embodiments of the disclosure. Any of the components of the computing device 2400 may include an IC device (e.g., the IC devices in FIGS. 1A and 1B) and/or an IC package (e.g., the IC package 2200 of FIG. 7). Any of the components of the computing device 2400 may include an IC device assembly (e.g., the IC device assembly 2300 of FIG. 8).

A number of components are illustrated in FIG. 9 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 9, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices as described herein may be particularly advantageous for use as part of ESD circuits protecting power amplifiers, low-noise amplifiers, filters (including arrays of filters and filter banks), switches, or other active components. In some embodiments, IC devices as described herein may be used in PMICs, e.g., as a rectifying diode for large currents. In some embodiments, IC devices as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an IC structure, including a first layer including first structures and second structures, the first structures alternating with the second structures; and a second layer over the first layer, the second layer including a first block of a first polymer, the first polymer including a first main chain and a non-polar functional group attached to the first main chain, the first polymer having a molecular weight of at least 10 kilogram per mole, and a second block of a second polymer, the second polymer including a second main chain and a polar functional group attached to the second main chain, where the first block is connected to the second block through a chemical bond between the first main chain and the second main chain.

Example 2 provides the IC structure according to example 1, where an individual first structure includes a third polymer including an additional non-polar functional group and having a molecular weight of no greater than 10 kilogram per mole, and an individual second structure includes a fourth polymer including an additional polar functional group.

Example 3 provides the IC structure according to example 2, where the molecular weight of the first polymer is about 10 times greater than the molecular weight of the third polymer.

Example 4 provides the IC structure according to example 2 or 3, where the first block is over the individual first structure or the individual second structure.

Example 5 provides the IC structure according to example 4, where an edge of the first block is aligned with an edge of the individual first structure or the individual second structure.

Example 6 provides the IC structure according to any of the preceding examples, where an individual first structure is a first conductive structure, an individual second structure is a second conductive structure, the second layer is over the first layer in a first direction, and a dimension of the first conductive structure in a second direction perpendicular to the first direction is different from a dimension of the second conductive structure in the second direction.

Example 7 provides the IC structure according to example 6, where the first block is over the first conductive structure or the second conductive structure.

Example 8 provides a block copolymer, including a first polymer, including a first main chain and a non-polar functional group attached to the first main chain, the first polymer having a molecular weight of at least 10 kilogram per mole; and a second polymer, including a second main chain and a polar functional group attached to the second main chain, where the first main chain is connected to the second main chain through a chemical bond, and a monomer of the first main chain is the same as a monomer of the second main chain.

Example 9 provides the block copolymer according to example 8, where a block of the second polymer is between two blocks of the first polymer.

Example 10 provides the block copolymer according to example 9, where the block of the second polymer is between the two blocks of the first polymer in a direction, and a dimension of a first one of the two blocks of the first polymer in the direction is different from a dimension of a second one of the two blocks of the first polymer in the direction.

Example 11 provides the block copolymer according to any one of examples 8-10, where a molecular weight of the second polymer is the same or substantially the same as the molecular weight of the first polymer.

Example 12 provides the block copolymer according to any one of examples 8-11, where the non-polar functional group is a hydrophobic functional group.

Example 13 provides the block copolymer according to any one of examples 8-12, where the polar functional group is a hydrophilic functional group.

Example 14 provides the block copolymer according to any one of examples 8-13, where the first polymer has a different rigidity from the second polymer.

Example 14 provides the assembly according to example 13, where the first block is over the first conductive structure or the second conductive structure.

Example 15 provides a method for forming an IC device, including forming a layer with a first polymer over an underlayer, the first polymer including a protecting group and having a molecular weight of at least 10 kilogram/mol; exposing a portion of the layer to light to convert the first polymer in the portion to a second polymer, the second polymer including a functional group converted from the protecting group and having a solubility greater than the first polymer; forming an opening in the layer by dissolving the second polymer; and filling at least part of the opening with an electrically conductive material or a dielectric material.

Example 16 provides the method according to example 15, further including forming the underlayer, where forming the underlayer includes forming an additional layer with a third polymer, the third polymer including an additional protecting group and having a molecular weight of no greater than 10 kilogram/mol; exposing a portion of the additional layer to light to convert the third polymer in the portion to a fourth polymer, the fourth polymer including an additional functional group converted from the additional protecting group and having a solubility greater than the third polymer; and removing the portion of the additional layer by dissolving the fourth polymer.

Example 17 provides the method according to example 16, where the third polymer includes a first molecule and a second molecule, each of the first molecule and the second molecule includes the additional protecting group and a functional group, and the first molecule is connected to the second molecule through cross-linking between the function group in the first molecule and the additional protecting group in the second molecule.

Example 18 provides the method according to example 17, where a number the function group in the third polymer is the same or substantially the same as a number of the additional protecting group in the third polymer.

Example 19 provides the method according to example 17 or 18, where the first molecule is converted to a third molecule in the fourth polymer from exposing the portion of the additional layer to the light, the second molecule is converted to a fourth molecule in the fourth polymer from exposing the portion of the additional layer to the light, and the third molecule is not connected to the fourth molecule.

Example 20 provides the method according to any one of examples 15-19, further including exposing an additional portion of the layer to light to convert the first polymer in the additional portion to the second polymer, where a dimension of the additional portion in a direction in parallel with the layer is different from a dimension of the portion in the direction.

Example 21 provides an IC package, including an IC device at least partially fabricated using the IC structure according to any one of examples 1-7, the block copolymer according to any one of examples 8-15, or the method according to any one of examples 15-20; and a further IC component, coupled to the device.

Example 22 provides the IC package according to example 21, where the further IC component includes one of a package substrate, an interposer, or a further IC die.

Example 23 provides the IC package according to example 21 or 22, where the IC device may include, or be a part of, at least one of a memory device, a computing device, a wearable device, a handheld electronic device, and a wireless communications device.

Example 24 provides an electronic device, including a carrier substrate; and the IC device according to any one of examples 21-23 and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

Example 34 provides the method according to any one of examples 15-20, further including processes for forming the IC device according to any one of claims 21-23.

Example 35 provides the method according to any one of examples 15-20, further including processes for forming the IC package according to any one of the claims 21-23.

Example 36 provides the method according to any one of examples 15-20, further including processes for forming the electronic device according to any one of the claims 24-33.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a first layer comprising first structures and second structures, the first structures alternating with the second structures; and
a second layer over the first layer, the second layer comprising:
a first block of a first polymer, the first polymer comprising a first main chain and a non-polar functional group attached to the first main chain, the first polymer having a molecular weight of at least 10 kilogram per mole, and
a second block of a second polymer, the second polymer comprising a second main chain and a polar functional group attached to the second main chain,
wherein the first block is connected to the second block through a chemical bond between the first main chain and the second main chain.

2. The IC structure according to claim 1, wherein:
an individual first structure comprises a third polymer comprising an additional non-polar functional group and having a molecular weight of no greater than 10 kilogram per mole, and
an individual second structure comprises a fourth polymer comprising an additional polar functional group.

3. The IC structure according to claim 2, wherein the molecular weight of the first polymer is about 10 times greater than the molecular weight of the third polymer.

4. The IC structure according to claim 2, wherein the first block is over the individual first structure or the individual second structure.

5. The IC structure according to claim 4, wherein an edge of the first block is aligned with an edge of the individual first structure or the individual second structure.

6. The IC structure according to claim 1, wherein:
an individual first structure is a first conductive structure,
an individual second structure is a second conductive structure,
the second layer is over the first layer in a first direction, and
a dimension of the first conductive structure in a second direction perpendicular to the first direction is different from a dimension of the second conductive structure in the second direction.

7. The IC structure according to claim 6, wherein the first block is over the first conductive structure or the second conductive structure.

8. A block copolymer, comprising:
a first polymer, comprising a first main chain and a non-polar functional group attached to the first main chain, the first polymer having a molecular weight of at least 10 kilogram per mole; and
a second polymer, comprising a second main chain and a polar functional group attached to the second main chain,
wherein the first main chain is connected to the second main chain through a chemical bond, and a monomer of the first main chain is the same as a monomer of the second main chain.

9. The block copolymer according to claim 8, wherein a block of the second polymer is between two blocks of the first polymer.

10. The block copolymer according to claim 9, wherein the block of the second polymer is between the two blocks of the first polymer in a direction, and a dimension of a first one of the two blocks of the first polymer in the direction is different from a dimension of a second one of the two blocks of the first polymer in the direction.

11. The block copolymer according to claim 8, wherein a molecular weight of the second polymer is the same or substantially the same as the molecular weight of the first polymer.

12. The block copolymer according to claim 8, wherein the non-polar functional group is a hydrophobic functional group.

13. The block copolymer according to claim 8, wherein the polar functional group is a hydrophilic functional group.

14. The block copolymer according to claim 8, wherein the first polymer has a different rigidity from the second polymer.

15. A method for forming an integrated circuit (IC) device, comprising:
forming a layer with a first polymer over an underlayer, the first polymer comprising a protecting group and having a molecular weight of at least 10 kilogram per mole;
exposing a portion of the layer to light to convert the first polymer in the portion to a second polymer, the second polymer comprising a functional group converted from the protecting group and having a solubility greater than the first polymer;
forming an opening in the layer by dissolving the second polymer; and
filling at least part of the opening with an electrically conductive material or a dielectric material.

16. The method according to claim 15, further comprising forming the underlayer, wherein forming the underlayer comprises:
forming an additional layer with a third polymer, the third polymer comprising an additional protecting group and having a molecular weight of no greater than 10 kilogram per mole;
exposing a portion of the additional layer to light to convert the third polymer in the portion to a fourth polymer, the fourth polymer comprising an additional functional group converted from the additional protecting group and having a solubility greater than the third polymer; and
removing the portion of the additional layer by dissolving the fourth polymer.

17. The method according to claim 16, wherein:
the third polymer comprises a first molecule and a second molecule,
each of the first molecule and the second molecule comprises the additional protecting group and a functional group, and
the first molecule is connected to the second molecule through cross-linking between the function group in the first molecule and the additional protecting group in the second molecule.

18. The method according to claim 17, wherein a number the function group in the third polymer is the same or substantially the same as a number of the additional protecting group in the third polymer.

19. The method according to claim 17, wherein:
the first molecule is converted to a third molecule in the fourth polymer from exposing the portion of the additional layer to the light,
the second molecule is converted to a fourth molecule in the fourth polymer from exposing the portion of the additional layer to the light, and
the third molecule is not connected to the fourth molecule.

20. The method according to claim 15, further comprising:
exposing an additional portion of the layer to light to convert the first polymer in the additional portion to the second polymer,
wherein a dimension of the additional portion in a direction in parallel with the layer is different from a dimension of the portion in the direction.
